(19) United States
(12) Patent Application Publication
(10) Pub. No.: US 2022/0206221 A1
(43) Pub. Date: Jun. 30, 2022

(54) OPTICAL DIE-LAST WAFER-LEVEL FANOUT PACKAGE WITH FIBER ATTACH CAPABILITY

(71) Applicant: ADVANCED MICRO DEVICES, INC., Santa Clara, CA (US)

(72) Inventors: SIDDHARTH RAVICHANDRAN, SUWANEE, GA (US); BRETT P. WILKERSON, AUSTIN, TX (US); RAHUL AGARWAL, SANTA CLARA, CA (US)

(21) Appl. No.: 17/134,756

(22) Filed: Dec. 28, 2020

(51) Int. Cl. G02B 6/136

(52) U.S. Cl. CPC G02B 6/136

(57) ABSTRACT

Manufacturing a semiconductor chip package with optical fiber attach capability includes preparing a photonic integrated circuit by etching a v-groove in a front side fiber coupling region; assembling the photonic integrated circuit on an organic redistribution layer; etching the organic redistribution layer; and attaching an optical fiber to the front side fiber coupling region.

### BACKGROUND

Photonic integrated circuits provide high bandwidth communication and are highly efficient. There are challenges in co-packaging photonic integrated circuits with other chips including systems-on-a-chip and memory chips.

### BRIEF DESCRIPTION OF THE DRAWINGS

FIG. 1A is a top view of a non-limiting example semiconductor chip package with optical fiber attach capability according to some embodiments.

FIG. 1B sets forth a cross-section of the example semiconductor ship package with optical fiber attach capability according to some embodiments.

FIG. 2A sets forth a flow chart illustrating an exemplary method for manufacturing a semiconductor chip package with optical fiber attach capability according to some embodiments.

FIG. 2B sets forth a flow chart illustrating an exemplary method for manufacturing a semiconductor chip package with optical fiber attach capability according to some embodiments.

FIG. 2C sets forth a flow chart illustrating an exemplary method for manufacturing a semiconductor chip package with optical fiber attach capability according to some embodiments.

FIG. 3A is a top view of a non-limiting example semiconductor chip package with optical fiber attach capability according to some embodiments.

FIG. 3B sets forth a cross-section of the example semiconductor ship package with optical fiber attach capability according to some embodiments.

FIG. 4A sets forth a flow chart illustrating an exemplary method for manufacturing a semiconductor chip package with optical fiber attach capability according to some embodiments.

FIG. 4B sets forth a flow chart illustrating an exemplary method for manufacturing a semiconductor chip package with optical fiber attach capability according to some embodiments.

### DETAILED DESCRIPTION

In some embodiments, a method of manufacturing a semiconductor chip package with optical fiber attach capability includes: preparing a photonic integrated circuit by etching a v-groove in a front side fiber coupling region; assembling the photonic integrated circuit on an organic redistribution layer; etching the organic redistribution layer; and attaching an optical fiber to the front side fiber coupling region.

In some embodiments, the method of manufacturing a semiconductor chip package with optical fiber attach capability includes preparing a system on a chip; and assembling the system on a chip on the organic redistribution layer. In some embodiments, the method of manufacturing a semiconductor chip package with optical fiber attach capability includes applying underfill; and etching the underfill. In some embodiments, the method of manufacturing a semiconductor chip package with optical fiber attach capability includes applying a sacrificial layer to protect the v-groove; and etching the sacrificial layer. In some embodiments, the method of manufacturing a semiconductor chip package with optical fiber attach capability includes releasing the organic redistribution layer from a first carrier; and transferring the photonic integrated circuit to a second carrier. In some embodiments, the method of manufacturing a semiconductor chip package with optical fiber attach capability includes releasing the photonic integrated circuit from the second carrier; and attaching the photonic integrated circuit to a substrate.

In some embodiments, the semiconductor chip package is a die-last wafer-level fanout package. In some embodiments, a mold compound encapsulates the photonic integrated circuit and the attached fiber.

In some embodiments, an apparatus with optical fiber attach capability includes: a system on a chip; a photonic integrated circuit with a v-groove in a front side fiber coupling region; an organic redistribution layer communicating with the system on a chip and photonic integrated circuit; and an optical fiber attached to the front side fiber coupling region.

In some embodiments, the apparatus is a die-last wafer-level fanout package. In some embodiments, a mold compound encapsulates the system on a chip, the photonic integrated circuit, and the attached fiber. In some embodiments, the attached fiber is secured by a glob top.

In some embodiments, a method of manufacturing a semiconductor chip package with optical fiber attach capability includes assembling a photonic integrated circuit on an organic redistribution layer; etching a back side fiber coupling region on the photonic integrated circuit by, thereby reducing a working distance of a lens to a grating coupler in the photonic integrated circuit; and attaching an optical fiber to the back side fiber coupling region.

In some embodiments, the method of manufacturing a semiconductor chip package with optical fiber attach capability includes preparing a system on a chip; and assembling the system on a chip on the organic redistribution layer. In some embodiments, the method of manufacturing a semiconductor chip package with optical fiber attach capability includes applying a mold compound; applying underfill; and etching the mold compound. In some embodiments, the method of manufacturing a semiconductor chip package with optical fiber attach capability includes releasing the organic redistribution layer from a first carrier; and transferring the photonic integrated circuit to a second carrier. In some embodiments, the method of manufacturing a semiconductor chip package with optical fiber attach capability includes releasing the photonic integrated circuit from the second carrier; and attaching the photonic integrated circuit to a substrate.

In some embodiments, the semiconductor chip package is a die-last wafer-level fanout package. In some embodiments, a mold compound encapsulates the photonic integrated circuit and the attached fiber.

In some embodiments, an apparatus with optical fiber attach capability includes: a system on a chip; a photonic integrated circuit with a thinned side back coupling region; an organic redistribution layer communicating with the system on a chip and photonic integrated circuit; and an optical fiber attached to the thinned back side fiber coupling region.

In some embodiments, the apparatus is a die-last wafer-level fanout package. In some embodiments, a mold compound encapsulates the system on a chip and the photonic integrated circuit.

In modern semiconductor chips, in order to improve upon the speed and capability of microchips, modular chips or chiplets are stacked in a package. In a three-dimensional (3D) chip, several chiplets are stacked vertically on an interposer. In a two-dimensional (2.5D) chip, the chiplets are stacked in a single layer on an interposer.

In fan-out packaging, chiplets are packaged on a redistribution layer with or without an interposer. In wafer level packaging, the dies are packaged while still on the wafer, rather than conventional packaging where the finished wafer is diced or singulated into individual chips then bonded and encapsulated. In die-first fan-out wafer level packaging, the dies are singulated then placed face-down or face-up on a temporary carrier. The die-first fan-out wafer level packaging then includes molding a reconstituted carrier, and building the redistribution layer, mounting solder balls and release from the temporary carrier, and dicing the reconstituted carrier into individual packages. In die-last fan-out wafer level packaging, the redistribution layer is built on a wafer, then the dies are singulated and assembled on the redistribution layer, solder balls are mounted and the temporary carrier is released, and the reconstituted wafer is diced into individual packages.

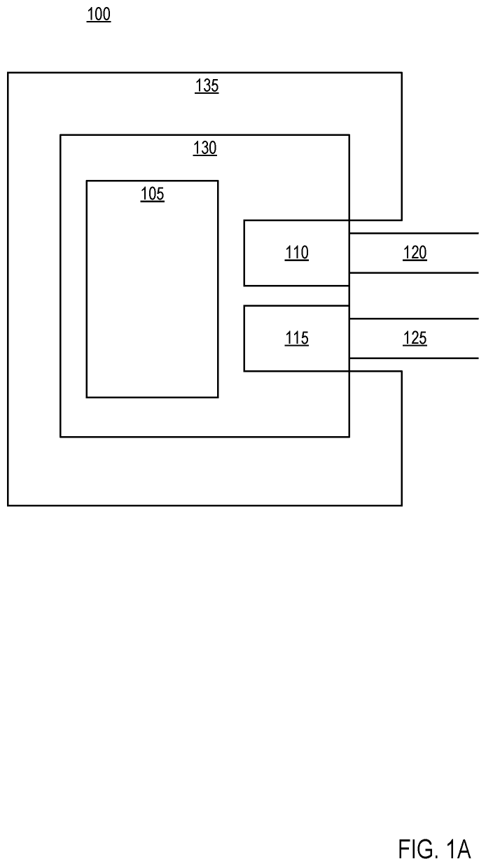

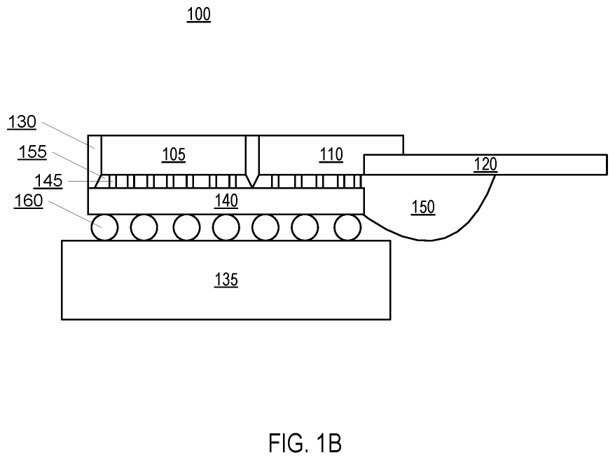

FIG. 1A is a top view of a non-limiting example semiconductor chip package 100. In some embodiments, the semiconductor chip package 100 is a die-last fan-out wafer level package. The semiconductor chip package 100 includes a system on a chip (SOC 105) and a photonic integrated circuit (PIC 110 and PIC 115). In some embodiments, the package 100 can include additional SOC or memory chips. Additionally, in some embodiments, the package 100 can include additional PIC.

The SOC 105 is an integrated circuit or chiplet that integrates several components including a central processing unit (CPU) and memory. In some embodiments, the SOC 105 includes input/output ports and other interconnects. The PIC 110 and PIC 115 are photonics ICs that provide fiber-optic communication with high bandwidth. The PIC 110 includes an attached fiber 120 and the PIC 115 includes an attached fiber 125. In some embodiments, PIC 110 and fiber 120 and PIC 115 and fiber 125 can include a lens arrangement and a coupler such as a grating coupler. The SOC 105 and PIC 110 and PIC 115 are encapsulated by a mold compound 130 and are assembled on a substrate 135. In some embodiments, the mold compound 130 can be a plastic composite material such as epoxy. In some embodiments, the substrate 135 can be organic laminate, glass or silicon. As shown in FIG. 1A, the substrate 135 and the mold compound 130 include a cutout where the fiber 120 and fiber 125 attach. The package may be covered by a lid (not shown).

For further explanation, FIG. 1B sets forth a cross-section of the example semiconductor ship package 100. As shown above in FIG. 1A, an SOC 105 and PIC 110 and PIC 115 are attached to an organic redistribution layer (RDL 140) with microbumps 145 secured by underfill 155 on bumps 160 on substrate 135. In some embodiments, the organic redistribution layer 140 is a polymer or layers of polymer. In some embodiments, bumps 160 can be a ball grid array (BGA) or controlled collapse chip connection (C4) bumps. SOC 105 and PIC 110 are encapsulated by mold compound 130. One PIC 110 and one fiber 120 is shown, due to the cross-section perspective. The fiber 120 is attached to a v-groove in a front side fiber coupling region in PIC 110. The fiber 120 is affixed with a glob top 150. In some embodiments, the glob top 150 can be an epoxy material.

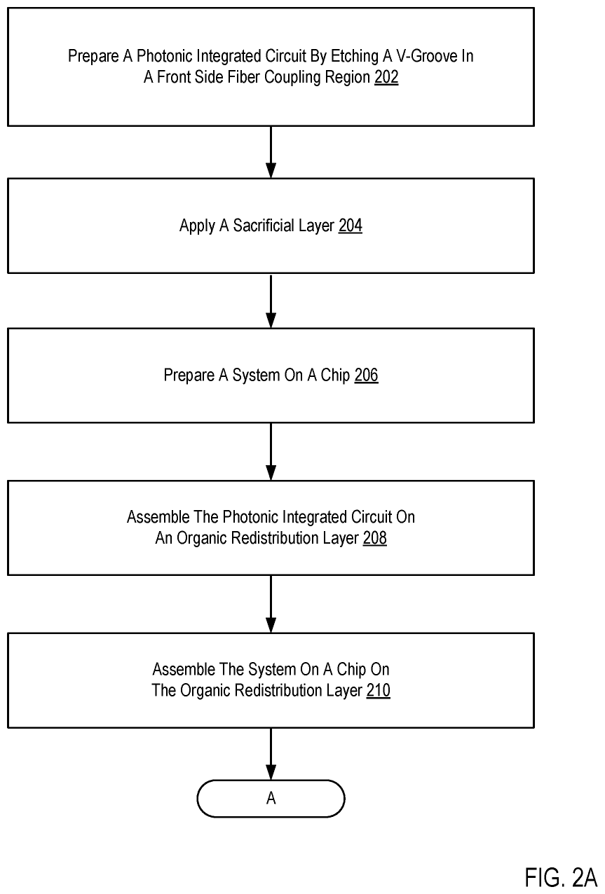

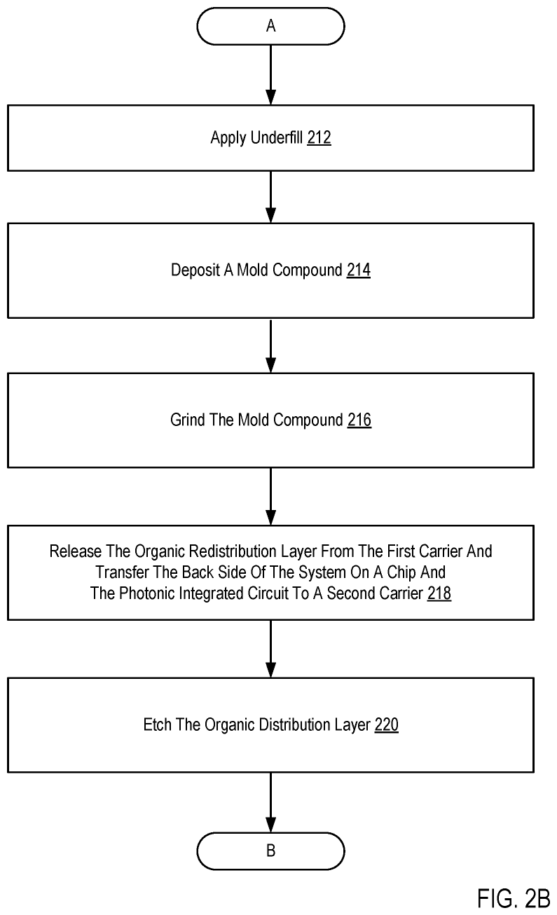

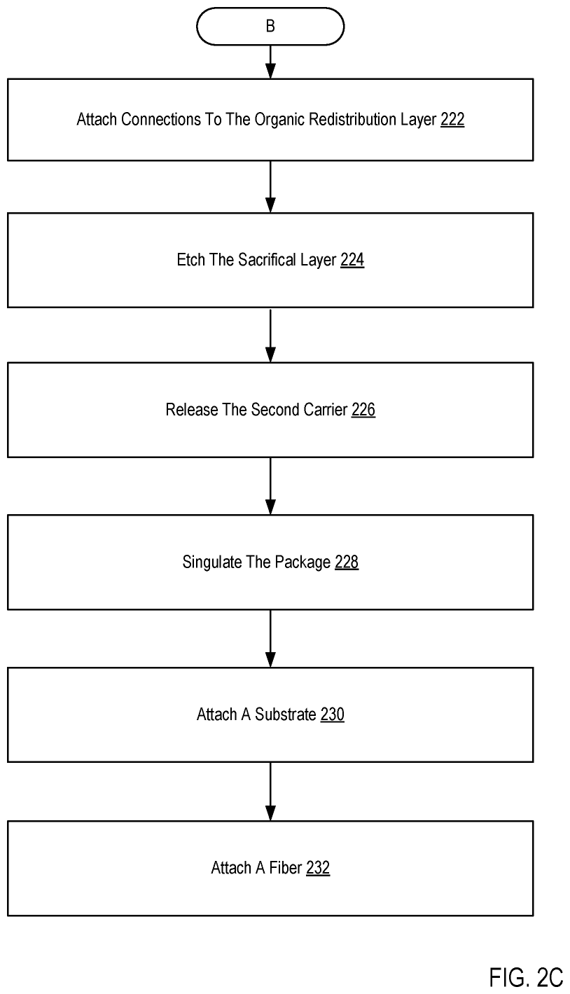

For further explanation, FIGS. 2A, 2B, and 2C set forth a flow chart illustrating an exemplary method for manufacturing a semiconductor chip package with optical fiber attach capability. Due to the number of steps, the flow chart has been divided into FIGS. 2A, 2B, and 2C. While the steps are shown in order, in some embodiments, the steps can be reordered or replaced or additional steps can be added. The method of FIG. 2A includes preparing 202 a photonic integrated circuit, including etching a v-groove in a front side fiber coupling region. The photonic integrated circuit is on a wafer that includes PIC 110 as well as many other PICs. In some embodiments, all of the PICs are prepared by etching a v-groove in a front side fiber coupling region.

The method of FIG. 2A also includes applying 204 a sacrificial layer over the v-groove in the front side fiber coupling region. Additionally, microbumps 145 are applied which are small solder balls that are connections to a redistribution layer. Additionally, the PIC wafer is diced or singulated into individual PICs. In some embodiments, the PIC wafer is singulated so that each PIC has a short extension of dummy silicon at the front side coupling region.

The method of FIG. 2A also includes preparing 206 a system on a chip. The system on a chip is on a wafer that includes SOC 105 as well as many other SOCs. Preparing 204 the SOC includes applying microbumps 145. Preparing 204 the SOC 105 also includes dicing or singulating the SOC wafer into individual SOCs.

The method of FIG. 2A also includes assembling 208 the PIC on an organic redistribution layer. Assembling the PIC 110 on the organic redistribution layer 140 includes placing the PIC microbumps 145 on their locations on the organic redistribution layer 140. As described above, in some embodiments, the organic redistribution layer 140 is a polymer or layers of polymer formed on a first carrier.

The method of FIG. 2A also includes assembling 210 the SOC on the organic redistribution layer. Assembling the SOC 105 on the organic redistribution layer 140 includes placing the SOC microbumps 145 on their locations on the organic redistribution layer 140 formed on the first carrier.

The method of FIG. 2B also includes applying 212 underfill. Applying 212 underfill 155 includes applying a resin or epoxy that flows. In some embodiments, the underfill 155 works to stabilize interconnections 145 and secure the positioning of the SOC 105 and PIC 110.

The method of FIG. 2B also includes depositing 214 a mold compound. Depositing 214 a mold compound includes depositing a mold compound 130 on the entire top and sides of the SOC 105 and PIC 110. In some embodiments, the mold compound 130 is an epoxy material.

The method of FIG. 2B also includes grinding 216 the mold compound. Grinding 216 the mold compound 130 includes grinding the mold compound 130 to expose the back side of the SOC 105 and PIC 110.

The method of FIG. 2B also includes releasing 218 the organic redistribution layer from the first carrier and transferring the back side of the SOC and PIC to a second carrier. Releasing 218 from the first carrier and transferring to the second carrier includes flipping the SOC 105 and PIC 110.

The method of FIG. 2B also includes etching 220 the organic redistribution layer. Etching 220 the organic redistribution layer 140 includes masking the organic redistribution layer 140 above the SOC 105 and PIC 110 and etching the organic redistribution layer 140 above the front side fiber coupling region.

The method of FIG. 2C also includes attaching 222 connections to the organic redistribution layer. In some embodiments, connections 160 can be a ball grid array (BGA) or controlled collapse chip connection (C4) bumps.

The method of FIG. 2C also includes etching 224 the sacrificial layer covering the v-groove in the front side fiber coupling region. Etching 224 the sacrificial layer includes removing the sacrificial layer that was applied to protect the v-groove. Removing the sacrificial layer exposes the v-groove in the front side fiber coupling region.

The method of FIG. 2C also includes releasing 226 the second carrier. Releasing 226 the second carrier includes releasing the back side of the SOC 105 and PIC 110 from the second carrier.

The method of FIG. 2C also includes singulating 228 the package. Singulating 228 the package includes dicing the reconstituted wafer to separate the packages. Singulating 228 the PIC 110 includes dicing through the v-groove to remove the excess dummy silicon.

The method of FIG. 2C also includes attaching 230 a substrate. Attaching 230 the substrate 135 includes placing the package on the BFA or C4 connectors 145.

The method of FIG. 2C also includes attaching 232 a fiber. Attaching 232 the fiber includes attaching the fiber and lens apparatus 120 to the v-groove at the front side fiber coupling region and securing the fiber and lens apparatus 120 with a glob top 150. In some embodiments, the fiber and lens apparatus 120 include other devices used for high bandwidth fiber communication.

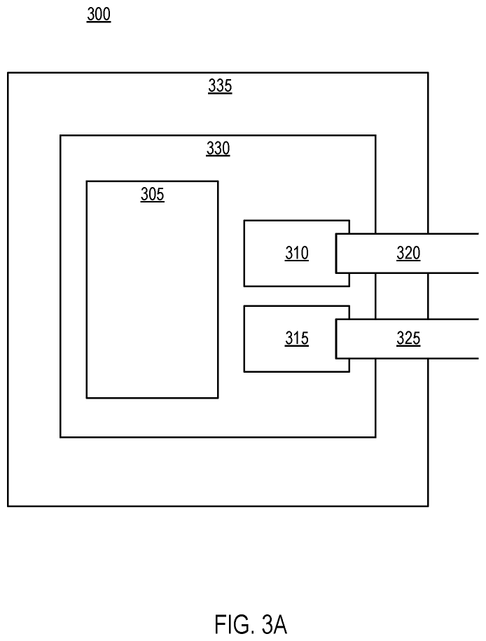

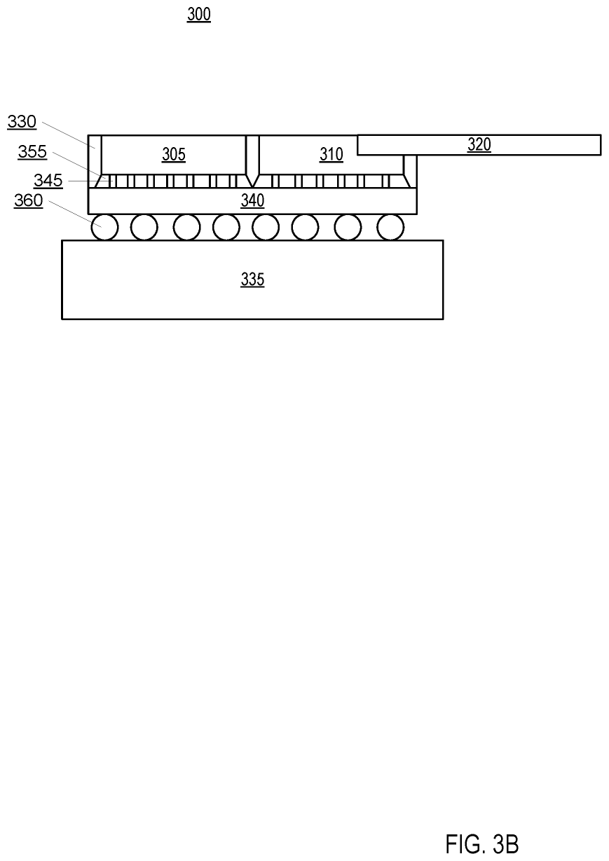

FIG. 3A is a top view of a non-limiting example semiconductor chip package 300. In some embodiments, the semiconductor chip package 300 is a die-last fan-out wafer level package. Similar to the semiconductor chip package 100 of FIGS. 1A and 1B, the semiconductor chip package 300 includes a system on a chip (SOC 305) and a photonic integrated circuit (PIC 310 and PIC 315). In some embodiments, the package 300 can include additional SOC or memory chips. Additionally, in some embodiments, the package 300 can include additional PIC.

Similar to the semiconductor chip package 100 of FIGS. 1A and 1B, the SOC 305 is an integrated circuit or chiplet that integrates several components including a central processing unit (CPU) and memory. In some embodiments, the SOC 305 includes input/output ports and other interconnects. The PIC 310 and PIC 315 are photonics ICs that provide fiber-optic communication with high bandwidth. The PIC 310 includes an attached fiber 320 and the PIC 315 includes an attached fiber 325. In some embodiments, PIC 310 and fiber 320 and PIC 315 and fiber 325 can include a lens arrangement and a coupler such as a grating coupler. The SOC 305 and PIC 310 and PIC 315 are encapsulated by a mold compound 330 and are assembled on a substrate 335. In some embodiments, the mold compound 330 can be a plastic composite material such as epoxy. In some embodiments, the substrate 335 can be glass or silicon. The package may be covered by a lid (now shown).

For further explanation, FIG. 3B sets forth a cross-section of the example semiconductor ship package 300. As shown above in FIG. 3A, an SOC 305 and PIC 310 and PIC 315 are attached to an organic redistribution layer (RDL 340) with microbumps 345 secured by underfill 355 on bumps 360 on substrate 135. In some embodiments, the organic redistribution layer 340 is a polymer or layers of polymer. In some embodiments, bumps 360 can be a ball grid array (BGA) or controlled collapse chip connection (C4) bumps. SOC 305 and PIC 310 are encapsulated by mold compound 330. One PIC 310 and one fiber 320 is shown, due to the cross-section perspective. The fiber 320 is attached to a back side fiber coupling region in PIC 310.

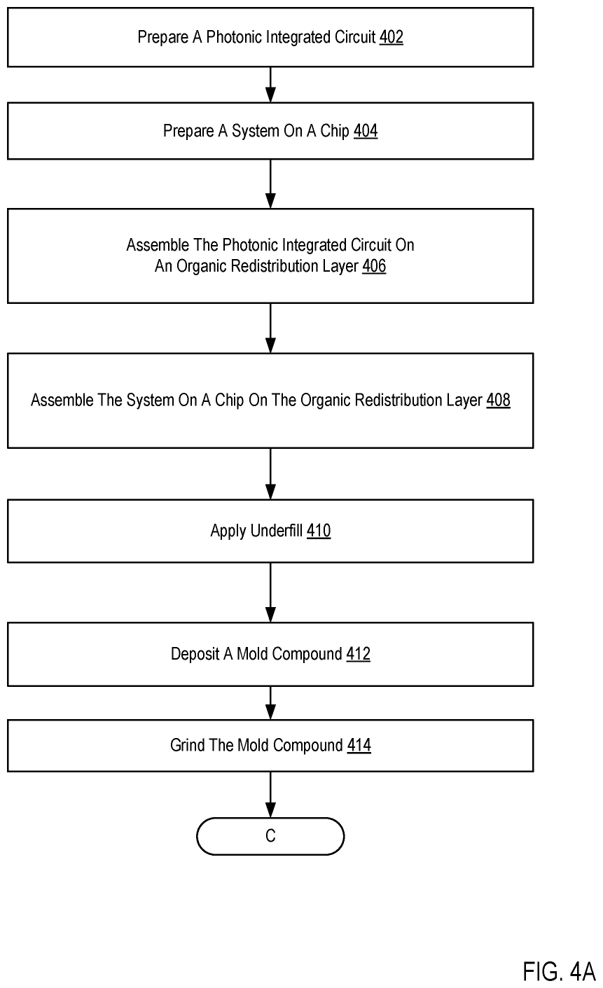

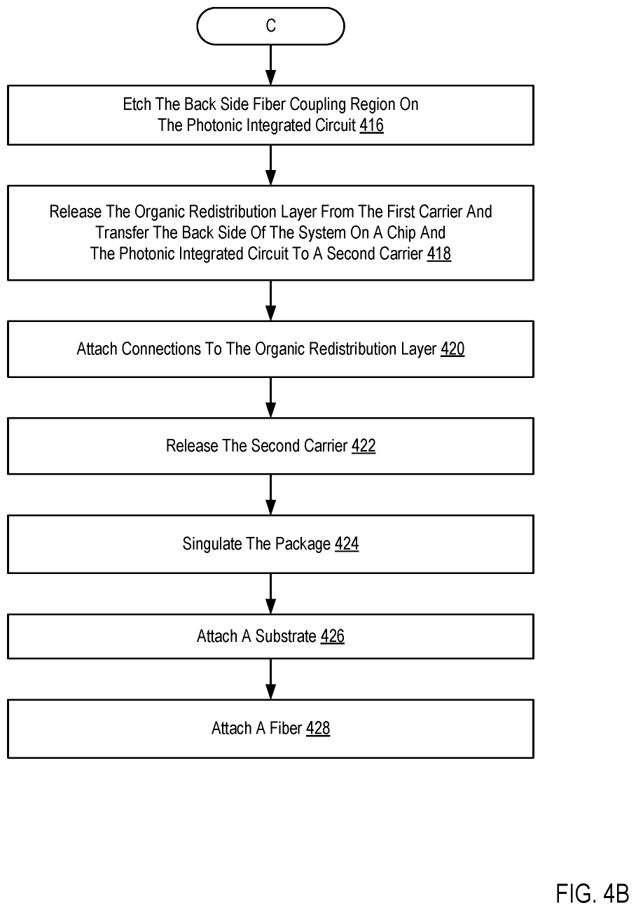

For further explanation, FIGS. 4A and 4B set forth a flow chart illustrating an exemplary method for manufacturing a semiconductor chip package with optical fiber attach capability. Due to the number of steps, the flow chart has been divided into FIGS. 4A and 4B. While the steps are shown in order, in some embodiments, the steps can be reordered or replaced or additional steps can be added. Similar to the exemplary method for manufacturing a semiconductor chip package with optical fiber attach capability 2A, 2B, and 2C, the method of FIG. 4A includes preparing 402 a photonic integrated circuit. Preparing 402 the PIC includes applying microbumps 345 which are small solder balls that are connections to a redistribution layer. The photonic integrated circuit is on a wafer that includes PIC 310 as well as many other PICS. Additionally, the PIC wafer is diced or singulated into individual PICS.

Similar to the exemplary method for manufacturing a semiconductor chip package with optical fiber attach capability 2A, 2B, and 2C, the method of FIG. 4A also includes preparing 404 a system on a chip. Preparing 404 the SOC includes applying microbumps 345. The system on a chip is on a wafer that includes SOC 305 as well as many other SOCs. Preparing 404 the SOC also includes dicing or singulating the SOC wafer into individual SOCs.

Similar to the exemplary method for manufacturing a semiconductor chip package with optical fiber attach capability 2A, 2B, and 2C, the method of FIG. 4A also includes assembling 406 the PIC on an organic redistribution layer. Assembling the PIC 310 on the organic redistribution layer 340 includes placing the PIC microbumps 345 on their locations on the organic redistribution layer 340. As described above, in some embodiments, the organic redistribution layer 340 is a polymer or layers of polymer formed on a first carrier.

Similar to the exemplary method for manufacturing a semiconductor chip package with optical fiber attach capability 2A, 2B, and 2C, the method of FIG. 4A also includes assembling 408 the SOC on the organic redistribution layer. Assembling the SOC 305 on the organic redistribution layer 340 includes placing the SOC microbumps 345 on their locations on the organic redistribution layer 340 formed on the first carrier.

Similar to the exemplary method for manufacturing a semiconductor chip package with optical fiber attach capability 2A, 2B, and 2C, the method of FIG. 4A also includes applying 410 underfill 355. Applying 410 underfill 355 includes applying a resin or epoxy that flows. In some embodiments, the underfill works to stabilize interconnections and secure the positioning of the SOC 305 and PIC 310.

Similar to the exemplary method for manufacturing a semiconductor chip package with optical fiber attach capability 2A, 2B, and 2C, the method of FIG. 4A also includes depositing 412 a mold compound. Depositing 412 a mold compound includes depositing a mold compound 330 on the entire top and sides of the SOC 305 and PIC 310. In some embodiments, the mold compound 330 is an epoxy material.

Similar to the exemplary method for manufacturing a semiconductor chip package with optical fiber attach capability 2A, 2B, and 2C, the method of FIG. 4A also includes grinding 414 the mold compound. Grinding 414 the mold compound 330 includes grinding the mold compound 330 to expose the back side of the SOC 305 and PIC 310.

The method of FIG. 4B also includes etching 416 the back side fiber coupling region on the PIC 310. Etching 416 the back side fiber coupling region includes masking the back side of the SOC 305 and PIC 310 and etching the back side fiber coupling region. Thinning the PIC 310 reduces the working distance of the lens apparatus 320 and a grating coupler in the PIC 310. Optical waves are guided by lens 320 into fiber 320 by a grating coupler and the shorter working distance by thinning the PIC 310 improves the coupling efficiency.

Similar to the exemplary method for manufacturing a semiconductor chip package with optical fiber attach capability 2A, 2B, and 2C, the method of FIG. 4B also includes releasing 418 the organic redistribution layer from the first carrier and transferring the back side of the SOC 305 and PIC 310 to a second carrier. Releasing 418 from the first carrier and transferring to the second carrier includes flipping the SOC 305 and PIC 310.

Similar to the exemplary method for manufacturing a semiconductor chip package with optical fiber attach capability 2A, 2B, and 2C, the method of FIG. 4B also includes attaching 420 connections to the organic redistribution layer. In some embodiments, connections 360 can be a ball grid array (BGA) or controlled collapse chip connection (C4) bumps.

Similar to the exemplary method for manufacturing a semiconductor chip package with optical fiber attach capability 2A, 2B, and 2C, the method of FIG. 4B also includes releasing 422 the second carrier. Releasing 422 the second carrier includes releasing the back side of the SOC 305 and PIC 310 from the second carrier.

Similar to the exemplary method for manufacturing a semiconductor chip package with optical fiber attach capability 2A, 2B, and 2C, the method of FIG. 4B also includes singulating 424 the package. Singulating 424 the package includes dicing the reconstituted wafer to separate the packages.

Similar to the exemplary method for manufacturing a semiconductor chip package with optical fiber attach capability 2A, 2B, and 2C, the method of FIG. 4B also includes attaching 426 a substrate. Attaching 426 the substrate 335 includes placing the package on the BFA or C4 connectors 345.

The method of FIG. 4B also includes attaching 428 a fiber. Attaching 428 the fiber includes attaching the fiber and lens apparatus 120 to the thinned back side fiber coupling region. In some embodiments, the fiber and lens apparatus 320 include other devices used for high bandwidth fiber communication.

In view of the explanations set forth above, readers will recognize that the benefits of manufacturing a semiconductor chip package with optical fiber attach capability include:
Improved co-packaging of photonic integrated circuits and other chiplets using a die-last wafer-level fanout approach.
Region of the die is presented to the inserted fiber that is typically encapsulated in packaging.

By co-packaging heterogenous chips or chiplets including system on a chip, memory, and photonic integrated circuits on one package, the package can perform specific functions in a small form factor. Using a die-last wafer-level fanout approach improves manufacturing including cost, time-to-market and yield.

The co-packaged system on a chip and photonic integrated circuits can be used in high bandwidth and efficient applications. The packages can be used in general datacenters or in specific purpose devices.

It will be understood from the foregoing description that modifications and changes can be made in various embodiments of the present disclosure. The descriptions in this specification are for purposes of illustration only and are not to be construed in a limiting sense. The scope of the present disclosure is limited only by the language of the following claims.

1-8. (canceled)

9. An apparatus with optical fiber attach capability, the apparatus comprising:
a system on a chip;
a photonic integrated circuit with a v-groove in a front side fiber coupling region;
an organic redistribution layer communicating with the system on a chip and photonic integrated circuit; and
an optical fiber attached to the front side fiber coupling region.

10. The apparatus of claim 9, wherein the apparatus is a die-last wafer-level fanout package.

11. The apparatus of claim 9, wherein a mold compound encapsulates the system on a chip, the photonic integrated circuit, and the attached fiber.

12. The apparatus of claim 9, wherein the attached fiber is secured by a glob top.

13-19. (canceled)

20. An apparatus with optical fiber attach capability, the apparatus comprising:
a system on a chip;
a photonic integrated circuit with a thinned side back coupling region;
an organic redistribution layer communicating with the system on a chip and photonic integrated circuit; and
an optical fiber attached to the thinned back side fiber coupling region, thereby reducing a working distance of a lens to a grating coupler in the photonic integrated circuit.

21. The apparatus of claim 20, wherein the apparatus is a die-last wafer-level fanout package.

22. The apparatus of claim 20, wherein a mold compound encapsulates the system on a chip and the photonic integrated circuit.

23. The apparatus of claim 11, wherein the mold compound comprises an epoxy material.

24. The apparatus of claim 12, wherein the glob top comprises an epoxy material.

25. The apparatus of claim 9, wherein the organic redistribution layer comprises a plurality of polymer layers.

26. The apparatus of claim 9, wherein the system on a chip and the photonic integrated circuit are attached to the organic redistribution layer with microbumps.

27. The apparatus of claim 26, wherein the microbumps are secured by an underfill.

28. The apparatus of claim 9, wherein a plurality of bumps is attached to the organic redistribution layer.

29. The apparatus of claim 28, wherein the plurality of bumps comprises a ball grid array.

30. The apparatus of claim 22, wherein the mold compound comprises an epoxy material.

31. The apparatus of claim 20, wherein the organic redistribution layer comprises a plurality of polymer layers.

32. The apparatus of claim 20, wherein the system on a chip and the photonic integrated circuit are attached to the organic redistribution layer with microbumps.

33. The apparatus of claim 32, wherein the microbumps are secured by an underfill.

34. The apparatus of claim 20, wherein a plurality of bumps is attached to the organic redistribution layer.

35. The apparatus of claim 34, wherein the plurality of bumps comprises a ball grid array.
